(19) United States
(12) Patent Application Publication
(10) Pub. No.: US 2011/0215795 A1
(43) Pub. Date: Sep. 8, 2011

(54) DETECTOR AND DETECTION METHOD

(75) Inventors: Tsuyoshi HIRAKI, Osaka (JP); Yasuhiko TOMIKAWA, Kyoto (JP); Mayumi YASUKOUCHI, Osaka (JP); Teruhiko IZUMI, Osaka (JP)

(73) Assignee: PANASONIC CORPORATION, Osaka (JP)

(21) Appl. No.: 13/106,663

(22) Filed: May 12, 2011

Related U.S. Application Data
(63) Continuation of application No. PCT/JP2009/006131, filed on Nov. 16, 2009.

(30) Foreign Application Priority Data
Nov. 14, 2008 (JP) 2008-292578
Jun. 15, 2009 (JP) 2009-141966

(51) Int. Cl. G01R 23/14

(52) U.S. Cl. 324/76.41

(57) ABSTRACT

A detector obtains an output signal from an input signal containing a target signal and outputs the output signal. The detector includes an amplifier configured to receive the input signal and the output signal, compare the input signal to the output signal to output a comparison result; an envelope generator configured to weight a first value and a second value having a sign opposite to that of the first value in accordance with the comparison result, integrate the weighted first value and the weighted second value, and output an integration result as the output signal; and a controller configured to control the envelope generator in accordance with the input signal. The controller controls the envelope generator to mitigate an increase in an absolute value of the integration result when the input signal contains a frequency component other than a frequency component of the target signal.

### CROSS-REFERENCE TO RELATED APPLICATION

This is a continuation of PCT International Application PCT/JP2009/006131 filed on Nov. 16, 2009, which claims priority to Japanese Patent Application No. 2008-292578 filed on Nov. 14, 2008, and Japanese Patent Application No. 2009-141966 filed on Jun. 15, 2009. The disclosures of these applications including the specifications, the drawings, and the claims are hereby incorporated by reference in their entirety.

### BACKGROUND

The present disclosure relates to detectors outputting signals having levels tracking peaks and bottoms of input signals.

A peak detector outputting a signal corresponding to a peak level of an input signal, and a bottom detector outputting a signal corresponding to a bottom level of an input signal in, for example, a circuit for audio signals are known. Japanese Patent Publication No. 2007-255909 teaches performing stable peak detection by setting a current for charging a capacitor to a predetermined value. Japanese Patent Publication No. S59-172105 relates to peak detection by digital signal processing.

### SUMMARY

However, a peak detection circuit shown in Japanese Patent Publication No. 2007-255909 or Japanese Patent Publication No. S59-172105 may also be affected by a noise component, resulting in inaccurate peak detection.

The present disclosure was made to address this problem. It is an objective of the present disclosure to perform relatively stable peak detection and bottom detection even when an input signal contains noise.

In an example embodiment of the present disclosure, a detector obtains an output signal from an input signal containing a target signal and outputs the output signal. The detector includes an amplifier configured to receive the input signal and the output signal, compare the input signal to the output signal to output a comparison result; an envelope generator configured to weight a first value and a second value having a sign opposite to that of the first value in accordance with the comparison result, integrate the weighted first value and the weighted second value, and output an integration result as the output signal; and a controller configured to control the envelope generator in accordance with the input signal. The controller controls the envelope generator to mitigate an increase in an absolute value of the integration result when the input signal contains a frequency component other than a frequency component of the target signal.

In another example embodiment of the present disclosure, a detector obtains an output signal from an input signal containing a target signal and outputs the output signal. The detector includes an amplifier configured to receive the input signal and the output signal, compare the input signal to the output signal to output a comparison result; an envelope generator configured to weight a first value and a second value having a sign opposite to that of the first value in accordance with the comparison result, integrate the weighted first value and the weighted second value, and output an integration result as the output signal; and a controller configured to control the envelope generator in accordance with the input signal. The controller controls the envelope generator to mitigate an increase in an absolute value of the integration result when a length of a period, in which the comparison result indicates that an absolute value of the input signal is greater than an absolute value of the output signal, is greater than a predetermined value.

In another example embodiment of the present disclosure, a detection method obtains an output signal from an input signal containing a target signal. The method includes comparing the input signal to the output signal; weighting a first value and a second value having a sign opposite to that of the first value in accordance with an obtained comparison result, integrating the weighted first value and the weighted second value, and outputting an integration result as the output signal; and mitigating an increase in an absolute value of the integration result when the input signal contains a frequency component other than a frequency component of the target signal.

In another example embodiment of the present disclosure, a detection method obtains an output signal from an input signal containing a target signal. The method includes comparing the input signal to the output signal; weighting a first value and a second value having a sign opposite to that of the first value in accordance with an obtained comparison result, integrating the weighted first value and the weighted second value, and outputting an integration result as the output signal; and mitigating an increase in an absolute value of the integration result when a length of a period, in which the comparison result indicates that an absolute value of the input signal is greater than an absolute value of the output signal, is greater than a predetermined value.

According to the embodiments of the present disclosure, a current value of a charging current is variable in accordance with an unnecessary component such as noise contained in an input signal. This allows stable peak detection etc. even when an input signal contains an unnecessary component such as noise.

### BRIEF DESCRIPTION OF THE DRAWINGS

FIG. 1 is a circuit diagram illustrating a detector according to an example embodiment of the present disclosure.

FIG. 2 illustrates waveforms of signals in a controller. The horizontal axis represents time, and the vertical axis represents the sizes of the signals.

FIG. 3 illustrates an example output signal of a detector.

FIG. 4 is an enlarged diagram illustrating an example output signal of a detector.

FIG. 5 is a circuit diagram illustrating a detector according to a first variation of the example embodiment.

FIG. 6 illustrates waveforms of signals in a controller.

FIG. 7 illustrates an example output signal of a detector.

FIG. 8 is an enlarged diagram illustrating an example output signal of a detector.

FIG. 9 is a circuit diagram illustrating a detector according to a second variation of the example embodiment.

FIG. 10 is a circuit diagram illustrating a detector according to a third variation of the example embodiment.

FIG. 11 illustrates a relationship between an input signal and an output signal of a detector.

FIG. 12 is a circuit diagram illustrating a detector according to a fourth variation of the example embodiment.

FIG. 13 is a circuit diagram illustrating a detector according to a fifth variation of the example embodiment.

### DETAILED DESCRIPTION

Embodiments of the present disclosure will be described hereinafter with reference to the drawings. The same reference characters are used to represent equivalent elements. In the drawings, solid lines among functional blocks represent electrical coupling. In the specification, the term “coupling” denotes direct or indirect electrical connection, and the term “indirect” refers to existence of an element between the coupled elements.

### Outline

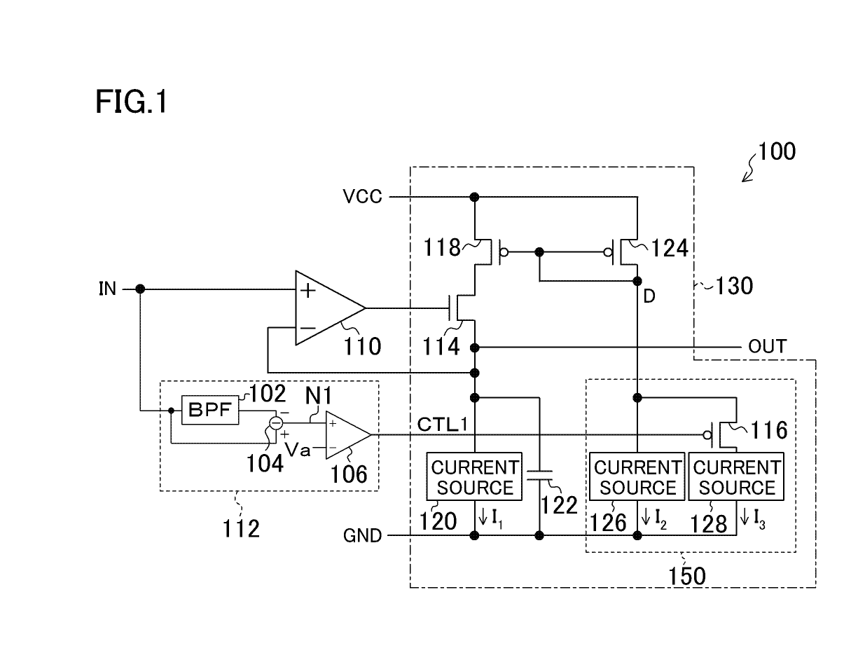

FIG. 1 is a circuit diagram illustrating a detector 100 according to an example embodiment of the present disclosure. The detector 100 receives an input signal IN. The input signal IN is, for example, a wobble signal read out from an optical disk. The detector 100 detects an envelope of the input signal IN, and outputs the detected envelope as an output signal OUT. Envelope detection is also called “peak detection,” and is referred to as “detection” in this specification for simplicity.

The detector 100 includes an operational amplifier 110, an attack gain controller 112, and an envelope generator 130. The envelope generator 130 includes an n-channel MOS transistor 114, p-channel MOS transistors 116, 118, and 124, current sources 120, 126, and 128, and a capacitor 122.

The input signal IN is input to a non-inverting input terminal of the operational amplifier 110, and the attack gain controller 112. An output of the operational amplifier 110 is coupled to a gate of the n-channel MOS transistor 114. An output CTL1 of the attack gain controller 112 is coupled to a gate of the p-channel MOS transistor 116.

The p-channel MOS transistor 118, the n-channel MOS transistor 114, and the current source 120 are provided between power supply potential VCC and ground potential GND, and are coupled in series. The output signal OUT is output from a node at which the n-channel MOS transistor 114 is coupled to the current source 120. The capacitor 122 is provided between the ground potential GND and the node at which the n-channel MOS transistor 114 is coupled to the current source 120.

An inverting input terminal of the operational amplifier 110 is coupled to the node at which the n-channel MOS transistor 114 is coupled to the current source 120. In other words, the operational amplifier 110 receives the output signal OUT at the inverting input terminal. Since the operational amplifier 110 has an extremely high gain, the operational amplifier 110 substantially functions as a comparator comparing the input signal IN to the output signal OUT of the detector 100.

The p-channel MOS transistor 124, and the current source 126 are provided between the power supply potential VCC and the ground potential GND, and are coupled in series. A gate of the p-channel MOS transistor 118 and a gate of the p-channel MOS transistor 124 are coupled to a drain of the p-channel MOS transistor 124. Therefore, the p-channel MOS transistor 118 and the p-channel MOS transistor 124 function as a current mirror.

The p-channel MOS transistor 116 and the current source 128 are provided between the drain of the p-channel MOS transistor 124 and the ground potential GND, and are coupled in series.

In general, the input signal IN contains a “target signal” from which the envelope is to be extracted by detection, and “noise” having a frequency component (unnecessary frequency component) other than a frequency component of the target signal. The target signal is typically a wobble signal of an optical disk. A wobble signal is detected based on wobbling of a recording track (groove) on an optical disk at a predetermined range of amplitude and frequency. The frequency is on the order of tens of kilohertz to tens of megahertz. The wobble signal includes a signal of 22.05 kHz in a CD-R/RW at 1× speed, and a signal of 13.1 MHz in a DVD+R at 16× speed, for example. When the rotational speed of an optical disk changes (e.g., when the speed of read and write operations changes), a frequency of the target signal may change. For simplicity, the following description is on assumption that the target signal has a constant frequency. The detectors described in the specification may receive RF signals as input signals.

Noise is generated by, e.g., a digital circuit included in an optical disk device. A frequency component contained in noise is called an “unnecessary frequency component” or a “noise component.” Noise may contain, e.g., an unnecessary frequency component of one severalth to one tenth order of a frequency component of a target signal. The unnecessary frequency component may typically change depending on time.

The attack gain controller 112 detects whether the input signal IN contains an unnecessary frequency component. When the attack gain controller 112 determines that the input signal IN substantially contains an unnecessary frequency component, the attack gain controller 112 controls the envelope generator 130 to mitigate an increase in the absolute value of the output signal OUT, which corresponds to an integration result described later. Specifically, at this time, the attack gain controller 112 outputs a high (H) level signal to a gate of the transistor 116 as a control signal CTL1. Therefore, when the input signal IN substantially contains an unnecessary frequency component, the p-channel MOS transistor 116 is turned off. The time “when the attack gain controller 112 determines that the input signal IN substantially contains an unnecessary frequency component” will be also referred to as “when the input signal IN contains noise” for simplicity.

On the other hand, when the attack gain controller 112 determines that the input signal IN does not substantially contain any unnecessary frequency component, the attack gain controller 112 outputs a low (L) level signal to the gate of the transistor 116 as the control signal CTL1. Thus, when the input signal IN does not substantially contain any unnecessary frequency component, the p-channel MOS transistor 116 is turned on. The time “when the attack gain controller 112 determines that the input signal IN does not substantially contain any unnecessary frequency component” will be also referred to as “when the input signal IN does not contain noise” for simplicity.

More specifically, the attack gain controller 112 includes a band pass filter (BPF) 102, a subtractor 104, and a comparator 106. The BPF 102 allows a frequency component close to the center frequency of the BPF 102 to pass. The center frequency is a frequency of a main frequency component of the target signal contained in the input signal IN. Therefore, the BPF 102 mainly outputs the target signal.

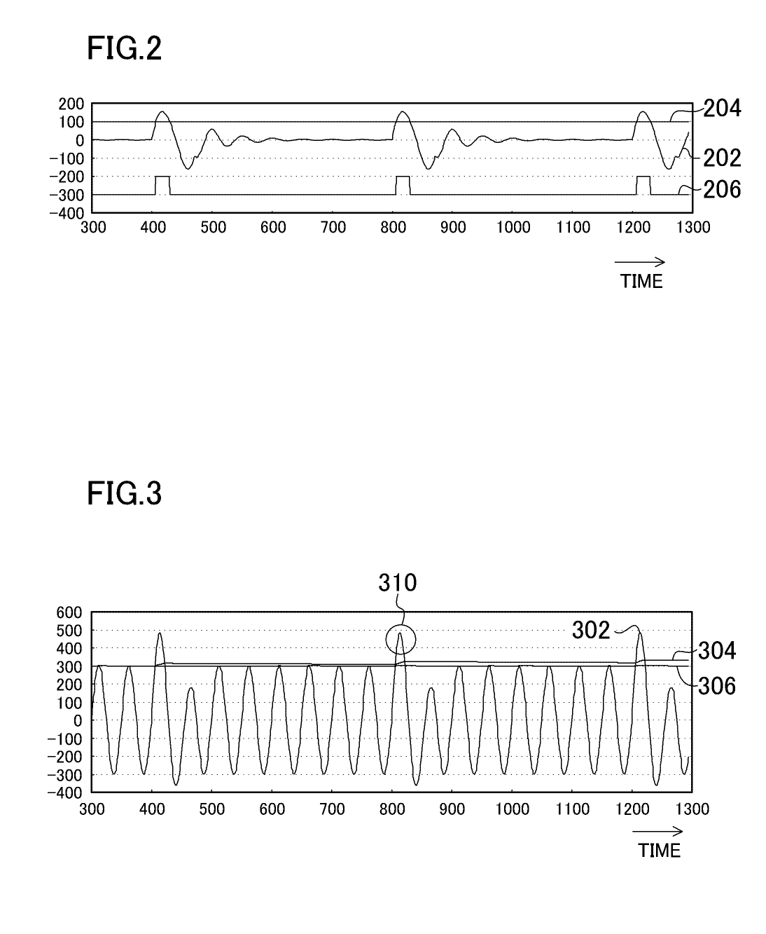

FIG. 2 illustrates waveforms of signals in the attack gain controller 112. The subtractor 104 mainly outputs the noise contained in the input signal IN by subtracting the output signal (i.e., target signal) of the BPF 102 from the input signal IN. The noise is represented by a reference numeral 202 of FIG. 2. The comparator 106 compares the noise 202 to a reference voltage Va, which is represented by a reference numeral 204 of FIG. 2. An output of the comparator 106 has an H level while the noise 202 is larger than the reference voltage Va. The output is represented by a reference numeral 206 of FIG. 2. The output 206 of the comparator 106 is input to the gate of the transistor 116 as the output CTL1 of the attack gain controller 112.

### Attack Gain

In general, detection is performed by mainly using an “attack gain” when an input signal exceeds a detection level. Specifically, when the input signal exceeds the detection level, the attack gain is mainly integrated, and a voltage corresponding to the integral value is output as the output signal OUT. The current sources 126 and 128, and the p-channel MOS transistor 116 determining an attack gain of the detector 100 form an attack gain generator 150. A current passing through the attack gain generator 150 corresponds to the attack gain. In the description, the value of the attack gain is regarded as a positive value.

The operational amplifier 110 receives the input signal IN and the output signal OUT, and compares the input signal IN to the output signal OUT, thereby outputting a comparison result to the n-channel MOS transistor 114. When the voltage of the input signal IN is higher than a voltage of the output signal OUT, the operational amplifier 110 outputs a signal having an H level. The H-level signal turns on the n-channel MOS transistor 114. The capacitor 122 is charged from the power supply potential VCC via the p-channel MOS transistor 118 and the n-channel MOS transistor 114. This charging raises the voltage of the output signal OUT.

The current sources 120, 126, and 128 supply currents I1, I2, and I3, respectively. When the input signal IN substantially contains an unnecessary frequency component, the transistor 116 is turned off. Thus, a current flowing through the transistor 124 is the current I2 supplied by the current source 126. Since the transistors 118 and 124 form a current mirror, a current flowing through the transistor 114 is also I2. Therefore, the current charging the capacitor 122 is (I2−I1). For example, where I1:I2:I3=1:2:19, the charging current is (I2−I1)=I1, which is substantially the attack gain.

On the other hand, when the input signal IN does not substantially contain any unnecessary frequency component, the transistor 116 is turned on. Thus, the current flowing through the transistor 124 is the sum (I2+I3) of the current I2 supplied by the current source 126 and the current I3 supplied by the current source 128. Since the transistors 118 and 124 form a current mirror, the current flowing through the transistor 114 is also (I2+I3). Therefore, the current charging the capacitor 122 is (I2+I3−I1). For example, where I1:I2:I3=1:2:19, the charging current is (I2+I3−I1)=20·I1, which is substantially the attack gain.

In short, when the input signal IN contains noise, the charging current is small (e.g., (I2−I1)=I1). On the other hand, when the input signal IN does not contain noise, the charging current is large (e.g., (I2+I3−I1)=20·I1). When the input signal IN contains noise, tracking characteristics to the input signal IN can be reduced (i.e., the attack gain is reduced). On the other hand, when the input signal IN does not contain noise, tracking characteristics to the input signal IN can be increased (i.e., the attack gain is increased). With this feature, when the input signal IN contains noise, tracking of the output signal OUT to the noise can be reduced. This enables stable peak detection.

In the above specific example, the ratio of the substantial attack gain of the detector 100 where the input signal IN contains noise to that where the input signal IN does not contains noise is I1/20·I1=1/20. Specific values of the currents I1, I2, and I3 can be selected as appropriate in accordance with desired tracking characteristics.

### Droop Gain

In general, detection is performed by using a “droop gain” when an input signal falls below a detection level. Specifically, when the input signal falls below the detection level, the droop gain is mainly integrated, and a voltage corresponding to the integral value is output as the output signal OUT. The current I1 flowing through the current source 120 corresponds to the absolute value of the droop gain. In the description, the value of the droop gain is regarded as a negative value, since the capacitor 122 is discharged with the current I1.

When the voltage of the input signal IN is lower than the voltage of the output signal OUT, the operational amplifier 110 outputs a signal having an L level. The L-level signal turns off the n-channel MOS transistor 114. The capacitor 122 is not charged from the power supply potential VCC via the p-channel MOS transistor 118 and the n-channel MOS transistor 114. The capacitor 122 is discharged with the current I1 supplied by the current source 120. This discharging drops the voltage of the output signal OUT. Therefore, in the above specific example, the absolute value of the droop gain is equal to the attack gain which is used when the input signal IN contains noise.

Operation of the envelope generator 130 will be generally described. The envelope generator 130 weights the attack gain and the droop gain (i.e., multiplies the attack gain and the droop gain by respective weights) in accordance with the output value of the operational amplifier 110, and integrates the sum of the weighted attack gain and the weighted droop gain. Assume that a first case is where the output of the operational amplifier 110 indicates that the voltage of the input signal IN is higher than the voltage of the output signal OUT, and a second case is where the output of the operational amplifier 110 indicates that the voltage of the input signal IN is lower than the voltage of the output signal OUT.

Specifically, in the first case, the envelope generator 130 sets the weight of the attack gain to be equal to or greater than that in the second case, and the weight of the droop gain to be equal to or less than that in the second case. For example, in the above example, the weight of the attack gain is 1 (0 in the second case), and the weight of the droop gain is 1 (1 in the second case). In the second case, the envelope generator 130 sets the weight of the droop gain to be equal to or greater than that in the first case, and the weight of the attack gain to be equal to or less than that in the first case. For example, in the above example, the weight of the attack gain is 0, and the weight of the droop gain is 1. Note that at least one of the weight of the attack gain or the weight of the droop gain has different values in the first case and in the second case.

FIG. 3 illustrates an example of the output signal OUT of the detector 100. The detector 100 receives a signal 302 as the input signal IN. A conventional circuit outputs a signal 304. The detector 100 outputs a signal 306. The signal 304 is influenced by the noise component 310, and then the level of the signal 304 rises. On the contrary, the noise component 310 has little effect on the signal 306, resulting in no significant change in the level of the signal 306.

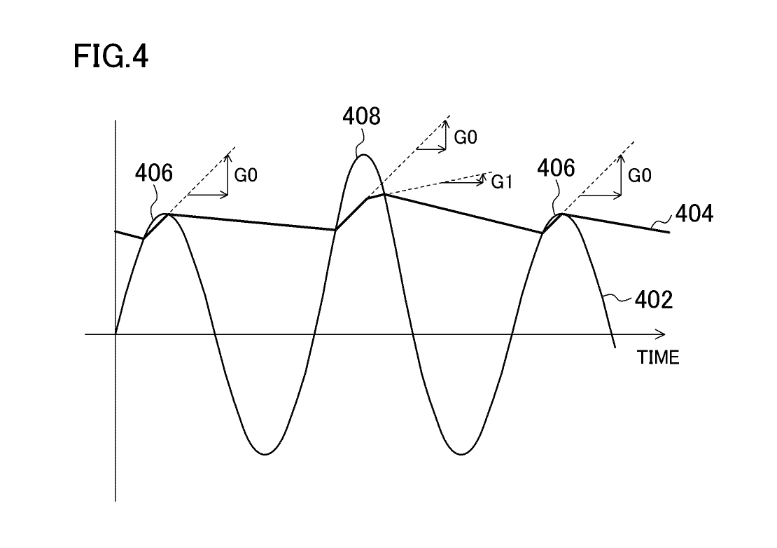

FIG. 4 is an enlarged diagram illustrating an example of the output signal OUT of the detector 100. The detector 100 receives a signal 402 as the input signal IN and outputs an output signal OUT 404. In a time period in which a target signal 406 exceeds the detection level, the level of the output signal 404 rises with a slope corresponding to an attack gain G0.

As compared to the target signal 406, a noise component 408 has a great peak value. The detector 100 detects such the noise 408. In a time period in which the noise component 408 exceeds the detection level, the level of the output signal 404 rises with a slope corresponding to the attack gain G0 until 206 of FIG. 2 becomes H. Once 206 of FIG. 2 becomes H, the level of the output signal 404 rises with a slope corresponding to an attack gain G1. At this time, 0<G1<G0, and G1/G0 is, e.g., 1/20 as described above. However, the attack gains G0 and G1 may be set to preferable values in accordance with characteristics of the target signal and the noise.

As such, the capacitor 122 integrates the attack gain or the droop gain in accordance with a comparison result of the operational amplifier 110, and the integration result is output as the output signal OUT. The integration includes integration of the sum of the attack gains and the droop gains.

In the specification, an attack gain is used when the input signal exceeds the detection level. In an analog circuit, the attack gain corresponds to a charging current to a capacitive element such as the capacitor 122. Specifically, the charging current to the capacitive element may be increased to increase the attack gain. In a digital circuit, the attack gain corresponds to an increase in an output voltage per unit time. Specifically, the increment of the voltage per time step may be increased to increase the attack gain.

In the specification, an envelope is a line such as the signal 306 of FIG. 3 which connects peaks or bottoms of a signal as a whole. The envelope of the signal 402 includes a waveform of the output signal 404 including the period in which a value temporarily falls below the value of the signal 402 as shown in FIG. 4.

### First Variation

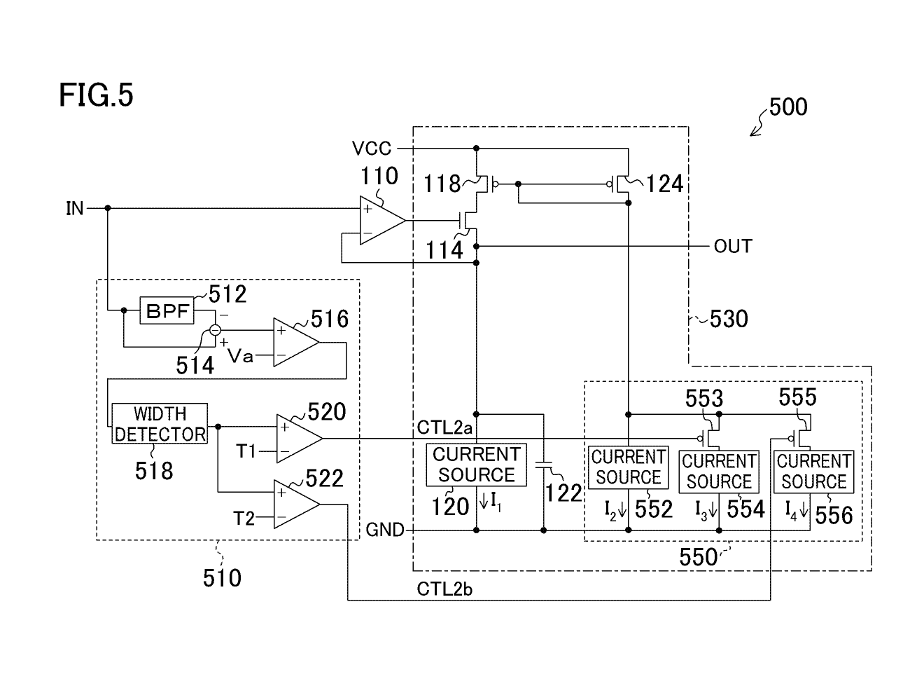

FIG. 5 is a circuit diagram illustrating a detector 500 according to a first variation of the example embodiment. The operation of the detector 500 is generally similar to the operation of the detector 100. Specifically, the detector 500 receives an input signal IN. The input signal IN is, for example, a wobble signal read out from an optical disk. The detector 500 detects an envelope of the target signal IN, and outputs the detected envelope as an output signal OUT.

The detector 500 differs from the detector 100 of FIG. 1 in that it includes an attack gain controller 510 and an envelope generator 530 in place of the attack gain controller 112 and the envelope generator 130, respectively. The envelope generator 530 differs from the envelope generator 130 of FIG. 1 in that it includes an attack gain generator 550 in place of the attack gain generator 150.

The attack gain controller 510 includes a BPF 512, a subtractor 514, a width detector 518, comparators 516, 520, and 522. The attack gain controller 510 may be also used as the attack gain controller 112. The BPF 512 allows a frequency component close to the center frequency of the BPF 512 to pass. The center frequency is a frequency of a main frequency component of the target signal contained in the input signal IN. Therefore, the BPF 512 mainly outputs the target signal.

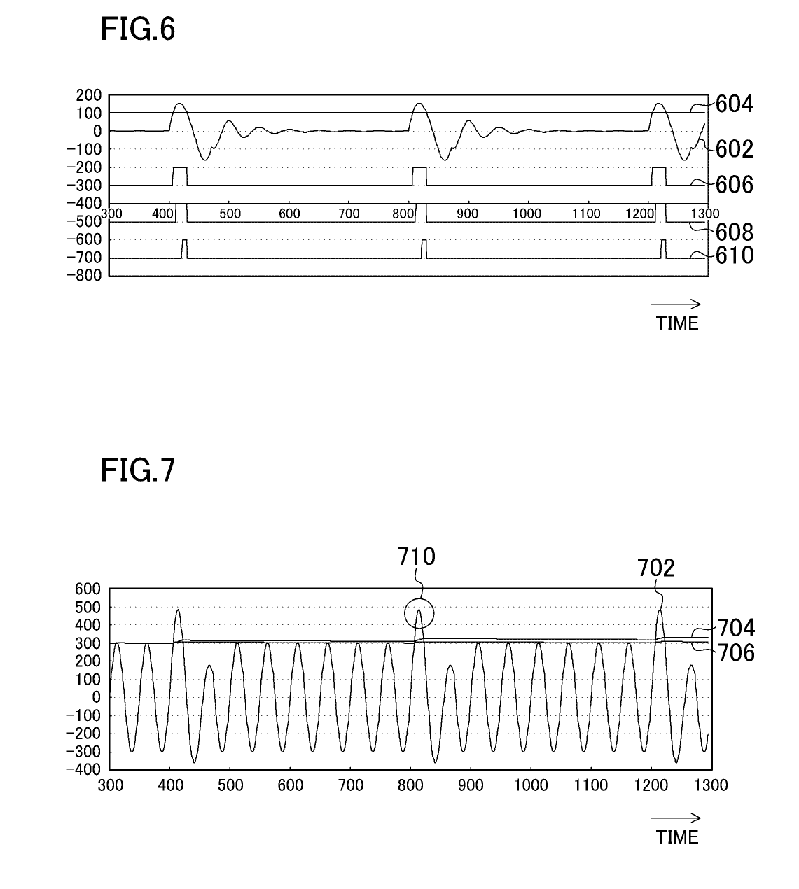

FIG. 6 illustrates waveforms of signals in the attack gain controller 510. The subtractor 514 mainly outputs the noise contained in the input signal IN, which is represented by a reference numeral 602 of FIG. 6, by subtracting the output signal (i.e., target signal) of the BPF 512 from the input signal IN. The comparator 516 compares the noise 602 to a reference voltage Va, which is represented by a reference numeral 604 of FIG. 6. An output of the comparator 516 has an H level in the period in which the noise 602 is larger than the reference voltage Va, which is represented by a reference numeral 606 of FIG. 6.

The width detector 518 detects the width of an output signal of the comparator 516. The comparator 520 compares the detected width to a threshold value T1, and outputs a comparison result as a control signal CTL2a. The comparison result is represented by a reference numeral 608 of FIG. 6. The comparator 522 compares the detected width to a threshold value T2, and outputs a comparison result as a control signal CTL2b. The comparison result is represented by a reference numeral 610 of FIG. 6. While the control signal CTL2a (608) has an H level, a p-channel MOS transistor 553 is turned off. While the control signal CTL2b (610) has an H level, a p-channel MOS transistor 555 is turned off.

The attack gain generator 550 includes current sources 552, 554, and 556. The above-described attack gain generator 150 generates attack gains of two different levels, in accordance with whether or not noise is contained. On the other hand, the attack gain generator 550 generates attack gains of three different levels, based on the width of a pulse forming noise as described later.

The current sources 120, 552, 554, and 556 supply current I1, I2, I3, and I4, respectively. The relationship is represented by I1<I2<I3<I4. As the width (e.g., a pulse width of the signal 606) increases, in which the noise component 602 is greater than a predetermined value, the charge current of the capacitor 122 can be reduced. As a result, the attack gain where the input signal IN contains noise can be reduced at three stages.

The detector 500 provides an advantage similar to the detector 100. That is, the above configuration reduces the influence of noise on the output signal OUT when the input signal IN contains the noise. This enables stable peak detection.

The detector 500 reduces the attack gain at three stages. However, the reduction levels of the attack gain are not limited to three stages, and may be n stages, where n is an integer of 2 or more, including the case of the detector 100. When the reduction in the attack gain is performed at three stages, the attack gain can be further reduced when the pulse width of the noise is large, as compared to the reduction at two stages. As a result, even when noise with a large pulse width is input, an unnecessary level rise of the output signal OUT does not occur. In other words, noise resistance is further increased by attack gain reduction at three or more stages.

FIG. 7 illustrates an example of the output signal OUT of the detector 500. The detector 500 receives a signal 702 as the input signal IN. A conventional circuit outputs a signal 704. The detector 500 outputs an output signal 706. The signal 704 is influenced by a noise component 710, and then the level of the signal 704 rises. On the contrary, the noise component 710 has little effect on the output signal 706, resulting in no significant change in the level of the output signal 706.

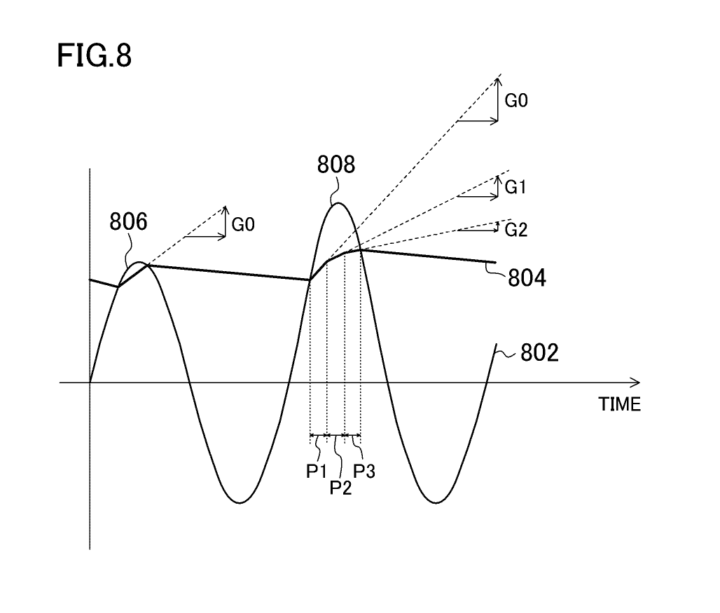

FIG. 8 is an enlarged diagram illustrating an example of the output signal OUT of the detector 500. The detector 500 receives a signal 802 as the input signal IN and outputs an output signal OUT (804). In a time period in which a target signal 806 exceeds the detection level, the level of the output signal 804 rises with a slope corresponding to the attack gain G0.

As compared to the target signal 806, a noise component 808 has a great peak value. The detector 500 detects such the noise 808. In a time period in which the noise component 808 exceeds the detection level, the level of the output signal 804 rises with a slope corresponding to the attack gain G0 in a period p1 until 606 and 608 of FIG. 6 become H. In a period p2, in which 606 and 608 become H and until 610 becomes H, the level of the output signal 804 rises with a slope corresponding to an attack gain G1. In the period in which 606, 608, and 610 are H, the output signal 804 rises with a slope corresponding to an attack gain G2. At this time, 0<G2<G1<G0.

As such, in the periods p1-p3, in which the input signal exceeds the detection level, different attack gains G0-G2 are applied to the input signal IN. The different attack gains are selected by detection of the pulse width of noise by the attack gain controller 510 and by control of the attack gain by the attack gain generator 550 based on the detection.

### Second Variation

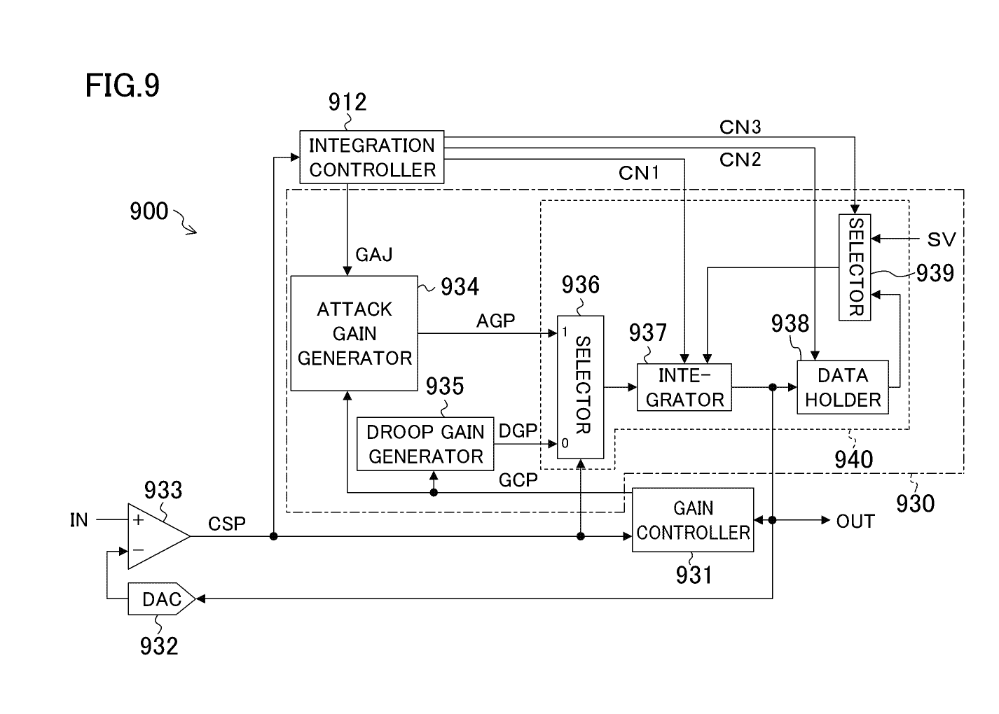

FIG. 9 is a circuit diagram illustrating a detector 900 according to a second variation of the example embodiment. The operation of the detector 900 is generally similar to the operation of the detector 100. Specifically, the detector 900 receives an input signal IN. The input signal IN is, for example, a wobble signal read out from an optical disk. The detector 900 detects an envelope of the target signal IN, and outputs the detected envelope as an output signal OUT.

The detector 900 includes a gain controller 931, a digital-to-analog (DA) converter (hereinafter referred to as a “DAC”) 932, an operational amplifier 933, an integration controller 912, and an envelope generator 930. The envelope generator 930 includes an attack gain generator 934, a droop gain generator 935, and a computing element 940. The computing element 940 includes selectors 936 and 939, an integrator 937, and a data holder 938.

The input signal IN is input to a non-inverting input terminal of the operational amplifier 933. The integrator 937 integrates a signal received from the selector 936, and outputs a digital signal corresponding to the integral value as the output signal OUT. The output signal OUT can be represented by a preferable bit number. For example, the output signal OUT may be an 8-bit digital signal. However, the output signal OUT is not limited to this specific bit number, and may be a digital signal with a preferable bit number.

The DAC 932 converts the output signal OUT to an analog signal, and outputs the signal to an inverting input terminal of the operational amplifier 933. The operational amplifier 933 has an extremely high gain. Thus, the operational amplifier 933 functions as a comparator comparing a voltage of the input signal IN to a voltage of the output signal OUT. The operational amplifier 933 outputs a comparison result CSP to the gain controller 931, the selector 936, and the integration controller 912.

When the voltage of the input signal IN is higher than an output voltage of the DAC 932, the operational amplifier 933 outputs an H-level signal, which is substantially a source voltage VCC, as the comparison result CSP. On the other hand, when the voltage of the input signal IN is lower than the output voltage of the DAC 932, the operational amplifier 933 outputs an L-level signal, which is substantially ground potential, as the comparison result CSP.

The integration controller 912 detects whether the length of a period, in which the comparison result indicates that the absolute value of the input signal IN is greater than the absolute value of the output signal, is greater than a predetermined length of time. When the integration controller 912 determines that the length of the period, in which the comparison result indicates that the absolute value of the input signal IN is greater than the absolute value of the output signal, is substantially greater than the predetermined length of time, the integration controller 912 controls the envelope generator 930 to mitigate an increase in the absolute value of the output signal OUT, which is equal to the integration result.

Specifically, the integration controller 912 outputs a control signal GAJ to the attack gain generator 934 based on continuity of an H level of the comparison result CSP. The “continuity” of the H level represents, for example, the length of the period of the H level, or a pulse number of the H level. The integration controller 912 compares, for example, the period of the H level of the comparison result CSP to a predetermined width, thereby generating the control signal GAJ corresponding to the comparison result. When the period of the H level of the comparison result CSP is larger than the predetermined width, the control signal GAJ corresponds to smaller one of two different attack gains.

As an alternative, the integration controller 912 may compare, for example, the pulse number of the H level of the comparison result CSP to a predetermined number, thereby generating the control signal GAJ corresponding to the comparison result. When the pulse number of the H level of the comparison result CSP is greater than the predetermined number, the control signal GAJ correspond to smaller one of two different attack gains.

As another alternative, the integration controller 912 may compare, for example, the length of the period of the H level of the comparison result CSP to two threshold values, thereby selectively outputting three different attack gains. Specifically, when the length of the period of the H level of the comparison result CSP is smaller than a first value, the integration controller 912 outputs the control signal GAJ corresponding to the attack gain G0 to the attack gain generator 934. When the length of the period of the H level of the comparison result CSP is greater than the first value, the integration controller 912 outputs the control signal GAJ corresponding to the attack gain G1, which is smaller than the attack gain G0, to the attack gain generator 934. When the length of the period of the H level of the comparison result CSP is greater than the first value and a second value, where the second value > the first value, the integration controller 912 outputs the control signal GAJ corresponding to the attack gain G2, which is smaller than the attack gain G1, to the attack gain generator 934. This alternative enables the operation shown in FIG. 8.

The attack gain generator 934 outputs a value corresponding to the control signal GAJ output from the integration controller 912, and a gain control signal GCP output from the gain controller 931 to the selector 936 as an attack gain AGP. The gain controller 931 sets default attack and droop gains in accordance with the frequency of the target signal. The gain controller 931 outputs the gain control signal GCP corresponding to the set default attack and droop gains. This enables supply of appropriate default attack and droop gains to the selector 936 even when the frequency of the target signal changes.

The droop gain generator 935 outputs a value corresponding to the gain control signal GCP output from the gain controller 931 to the selector 936 as the droop gain DGP. The attack gain AGP can be changed with the control signal GAJ from the integration controller 912, and has, for example, a positive value. On the other hand, the droop gain DGP is a value with a signal opposite to that of the attack gain AGP, and has, for example, a predetermined negative value. The absolute value of the attack gain AGP is greater than the absolute value of the droop gain DGP. These absolute values may be 1 or less.

For example, when the H level of the comparison result CSP does not have continuity exceeding a first predetermined value, the value of the attack gain AGP corresponds to the control signal GAJ from the integration controller 912, i.e., G0=20. When the H level of the comparison result CSP has the continuity exceeding the first predetermined value, the value of the attack gain AGP corresponds to the control signal GAJ from the integration controller 912, i.e., G1=4. When the H level of the comparison result CSP has continuity exceeding a second predetermined value, where the first predetermined value < the second predetermined value, the value of the attack gain AGP corresponds to the control signal GAJ from the integration controller 912, i.e., G2=1. The value of the droop gain DGP is −1. That is, when the comparison result CSP has an H level (i.e., in the period in which the input signal exceeds the detection level), the integration controller 912 detects the continuity of the H level of the comparison result CSP, and the control signal GAJ controls the attack gain AGP, thereby changing the attack gain AGP.

The selector 936 selects the attack gain AGP when the comparison result CSP has an H level, and selects the droop gain DGP when the comparison result CSP has an L level, to output the selected gain value to the integrator 937. The integrator 937 integrates an input value from the selector 936, and outputs the obtained integral value as the output signal OUT. As such, the DAC 932, the operational amplifier 933, the selector 936, and the integrator 937 form a feedback loop.

While the integration controller 912 outputs the control signal GAJ based on continuity of the H level of the comparison result CSP, the integration controller 912 may output similar signals as control signals CN1, CN2, and CN3. The integration controller 912 may control output timing of the control signal GAJ, CN1, CN2, or CN3 to be output at appropriate timing.

When the control signal GAJ, CN1, CN2, or CN3 indicates that the continuity of the H level of the comparison result CSP is detected, the envelope generator 930 operates to mitigate an increase in the absolute value of the integral value obtained by the integrator 937. Specifically, the integration controller 912 may output the control signal GAJ providing instructions for reducing the absolute value of the attack gain AGP as described above, or may output the control signal CN1 providing instructions for holding an integral value to the integrator 937. The integrator 937 holds the output integral value in accordance with the control signal CN1. The integration controller 912 allows the integrator 937 to hold the integral value until the continuity of the H level of the comparison result CSP is no more detected.

The integration controller 912 may output to the data holder 938, the control signal CN2 providing instructions for holding the value in place of the control signal CN1. In this case, the data holder 938 holds the integral value output from the integrator 937 in accordance with the control signal CN2 and outputs the integral value to the selector 939. The selector 939 outputs the value hold at the data holder 938 to the integrator 937. The integration controller 912 outputs to the integrator 937, the control signal CN1 providing instructions for setting the value input from the selector 939 to a new integral value. The integrator 937 sets the value input from the selector 939 to the new integral value.

A set value SV is input to the selector 939, and then the value is set at the integrator 937. Specifically, the integration controller 912 may output to the selector 939, the control signal CN3 providing instructions for selecting the set value SV in place of the control signal CN1. The selector 939 selects the set value SV and outputs the set value SV to the integrator 937. The integration controller 912 outputs to the integrator 937, the control signal CN1 providing instructions for setting the value input from the selector 939 to a new integral value. The integrator 937 sets the value input from the selector 939 to the new integral value. The set value SV is, for example, a value expected to stabilize the operation of the detector 900. Note that a preferable set value SV may be input from the outside the computing element 940.

When the continuity of the H level of the comparison result CSP is no more detected, the integration controller 912 outputs to the integrator 937, the control signal CN1 providing instructions for performing integration. The integrator 937 performs integration of an output of the selector 936 in accordance with the control signal CN1.

In the second variation, when the operational amplifier 933 outputs a signal having an H level, the continuity of the H level of the comparison result CSP is detected, and the attack gain AGP can be changed based on the detection result. This enables stable peak detection without causing overcharge due to tracking to the signal, even when the input signal IN contains an unnecessary component such as noise.

### Third Variation

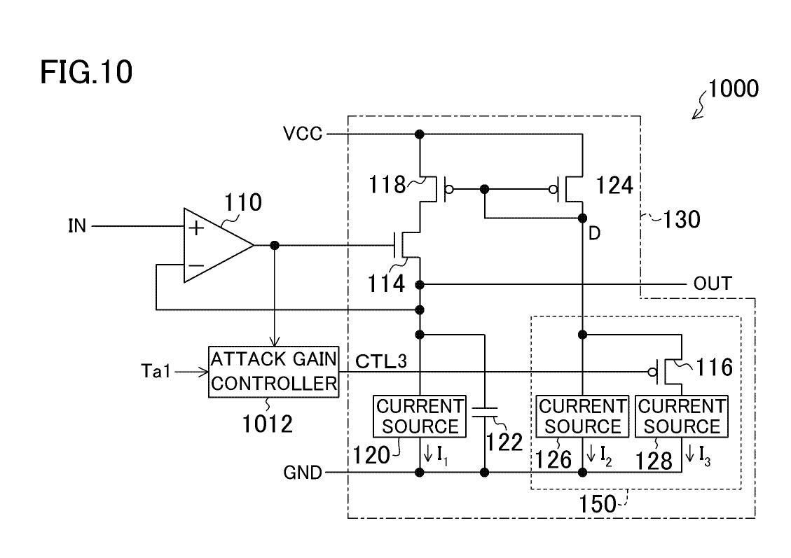

FIG. 10 is a circuit diagram illustrating a detector 1000 according to a third variation of the example embodiment. The operation of the detector 1000 is generally similar to the operation of the detector 100. Specifically, the detector 1000 receives an input signal IN. The input signal IN is, for example, a wobble signal read out from an optical disk. The detector 1000 detects an envelope of the target signal IN, and outputs the detected envelope as an output signal OUT.

The detector 1000 differs from the detector 100 in that an attack gain controller 1012 is used in place of the attack gain controller 112, and that the attack gain controller 1012 receives as an input, the output of the operational amplifier 110. The attack gain controller 1012 outputs an H level signal or an L level signal based on the width of the H level of the output of the operational amplifier 110. When the width of the H level of the output of the operational amplifier 110 is equal to or less than a predetermined value Ta1, the attack gain controller 1012 outputs an L level signal as a control signal CTL3. On the contrary, when the width of the H level of the output of the operational amplifier 110 exceeds the predetermined value Ta1, the attack gain controller 1012 outputs an H level signal as the control signal CTL3.

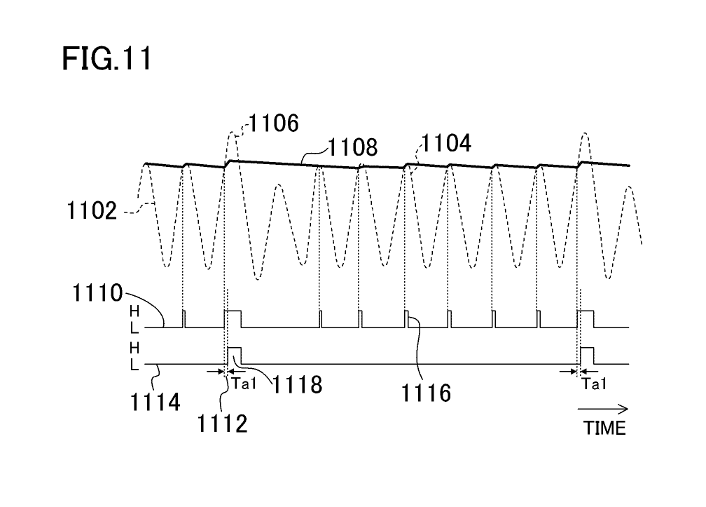

FIG. 11 illustrates a relationship between the input signal IN and the output signal OUT of the detector 1000. Operation of the detector 1000 will be described hereinafter with reference to FIGS. 10 and 11.

When a voltage of the input signal IN is larger than a voltage of the output signal OUT (i.e., when the operational amplifier 110 outputs a signal having an H level), and the width of the H level output from the operational amplifier 110 is equal to or less than the predetermined value Ta1, the control signal CTL3 has an L level. Thus, the p-channel MOS transistor 116 is turned on, and a charging current of a capacitor 112 becomes (I2+I3−I1). When the operational amplifier 110 outputs a signal having an H level, and the width of the H level output from the operational amplifier 110 exceeds the predetermined value Ta1, the control signal CTL3 has an H level. Thus, the p-channel MOS transistor 116 is turned off, and the charging current of the capacitor 112 becomes (I2−I1).

In short, when the operational amplifier 110 outputs a signal having an H level, the attack gain controller 1012 detects whether the width of the H level output from the operational amplifier 110 exceeds the predetermined value Ta1. Based on the detection result, the attack gain controller 1012 changes the level of the control signal CTL3. As a result, the attack gain controller 1012 can control turning on/off of the p-channel MOS transistor 116 to change the charging current of the capacitor 122. In the third variation, the charging current is changed as described above, thereby enabling stable peak detection without causing overcharge due to tracking to the signal, even when the input signal IN contains an unnecessary component such as noise.

An input signal 1102 contains a target signal 1104, and noise 1106 with a frequency component of, e.g., ⅛ of that of the target signal 1104. When the voltage of the input signal 1102 is larger than the voltage of an output signal 1108 (i.e., when the operational amplifier 110 outputs a signal having an H level), and the width of the H level of a signal 1110 output from the operational amplifier 110 is equal to or less than the predetermined value Ta1 (1112 in FIG. 11), the control signal CTL3 (1114 in FIG. 11) has an L level. On the other hand, when the operational amplifier 110 outputs a signal having an H level, and the width of the H level of the signal 1110 output from the operational amplifier 110 exceeds the predetermined value Ta1 (1112 in FIG. 11), the control signal CTL3 (1114 in FIG. 11) has an H level.

As such, determination is made based on whether the width of the H level of the output signal of the operational amplifier 110 is greater than a threshold value (e.g., the predetermined value Ta1), thereby ignoring a pulse 1116 of the target signal 1104 with a width equal to or less than the threshold value. This ensures tracking to the target signal 1104. When the noise 1106 is input, the attack gain is reduced in a period 1118 in which the width exceeds a predetermined value 1112.

### Fourth Variation

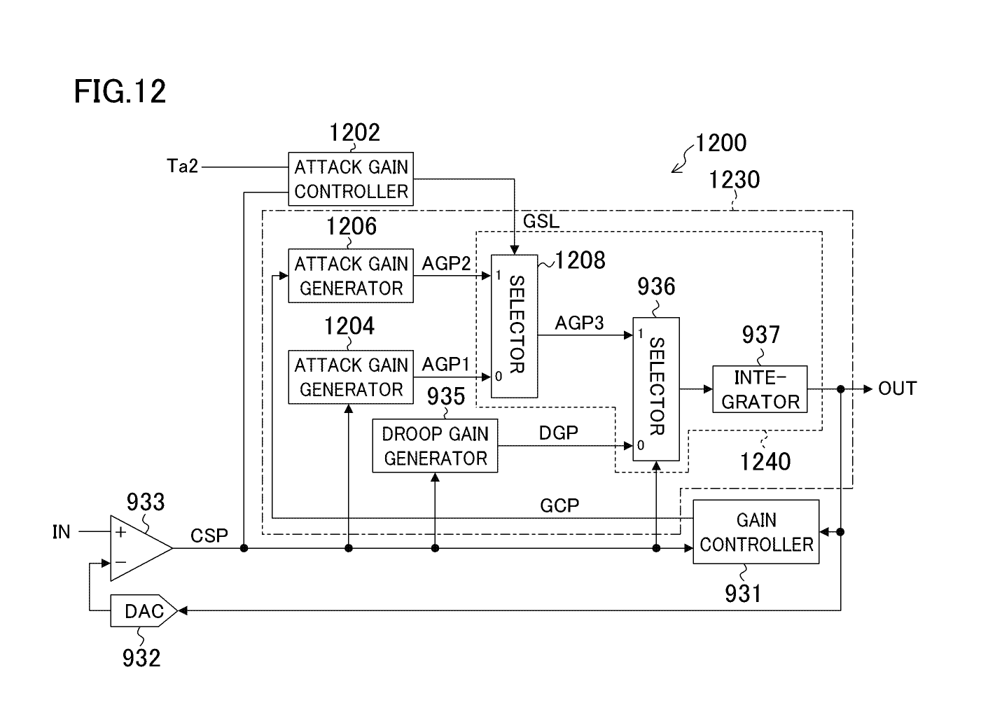

FIG. 12 is a circuit diagram illustrating a detector 1200 according to a fourth variation of the example embodiment. The operation of the detector 1200 is generally similar to the operation of the detector 1000. Specifically, the detector 1200 receives an input signal IN. The input signal IN is, for example, a wobble signal read out from an optical disk. The detector 1200 detects an envelope of the target signal IN, and outputs the detected envelope as an output signal OUT.

In the fourth variation, an attack gain controller 1202, attack gain generators 1204 and 1206, and a selector 1208 are used in place of the integration controller 912 and the attack gain generator 934 used in the detector 900. An envelope generator 1230 includes the attack gain generators 1204 and 1206, a droop gain generator 935, and a computing element 1240. The computing element 1240 includes selectors 936 and 1208, and an integrator 937.

The attack gain controller 1202 receives a comparison result CSP as an input, and outputs an H level signal or an L level signal based on the continuity of the H level of the comparison result CSP. When the continuity of the H level of the comparison result CSP is equal to or less than a predetermined value Ta2, the attack gain controller 1202 outputs an L level to the selector 1208 as a control signal GSL. On the contrary, when the continuity of the H level of the comparison result CSP exceeds the predetermined value Ta2, the attack gain controller 1202 outputs the H level signal to the selector 1208 as the control signal GSL.

The attack gain generator 1204 outputs to the selector 1208, the value corresponding to the gain control signal GCP output from the gain controller 931 as an attack gain AGP1. The attack gain generator 1206 outputs to the selector 1208, the value corresponding to the gain control signal GCP output from the gain controller 931 as an attack gain AGP2. When the control signal GSL has an L level, the selector 1208 selects the attack gain AGP1, and outputs the attack gain AGP1 to the selector 936 as an attack gain AGP3. When the control signal GSL has an H level, the selector 1208 selects the attack gain AGP2, and outputs the attack gain AGP2 to the selector 936 as the attack gain AGP3.

Similar to the second variation, the droop gain generator 935 outputs to the selector 936, the value corresponding to the gain control signal GCP output from the gain controller 931 as the droop gain DGP. The attack gain AGP1 and the attack gain AGP2 have, for example, predetermined positive values, and the droop gain DGP is, for example, a predetermined negative value. The relationship among the absolute values of these values is represented by |AGP1|>|AGP2|>=|DGP|.

When the comparison result CSP has an H level, the attack gain controller 1202 detects the continuity of the H level of the comparison result CSP, and controls the selector 1208 with the control signal GSL based on the continuity. As a result, the attack gain controller 1202 changes the attack gain AGP3.

The selector 936 selects the attack gain AGP3 output from the selector 1208 when the comparison result CSP has an H level, and selects the droop gain DGP output from the droop gain generator 935 when the comparison result CSP has an L level. The selector 936 outputs the selected gain value to the integrator 937. The integrator 937 integrates the gain value from the selector 936, and outputs the obtained integral value as the output signal OUT.

In the fourth variation, when the operational amplifier 933 outputs a signal having an H level, the attack gain controller 1202 determines whether the continuity of the H level of the comparison result CSP exceeds the predetermined value Ta2. The selector 1208 changes the attack gain AGP3 based on the continuity of the H level of the comparison result CSP. For example, the selector 1208 selectively outputs one of the two different attack gain AGP1 or AGP2. This enables stable peak detection without causing overcharge due to tracking to the signal, even when the input signal IN contains an unnecessary component such as noise.

### Fifth Variation

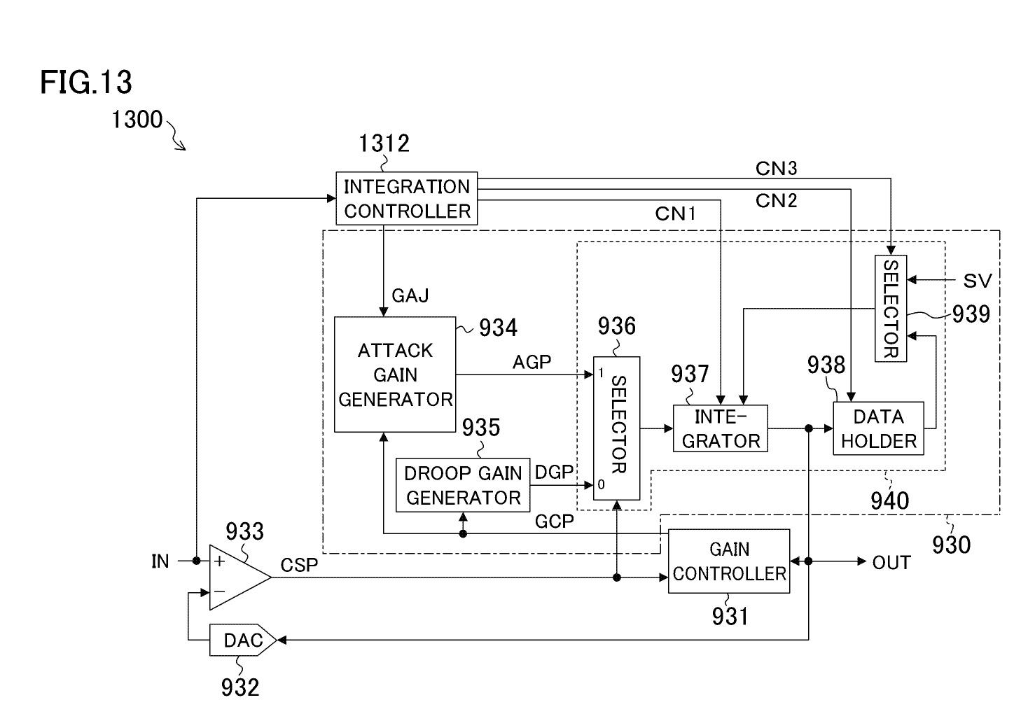

FIG. 13 is a circuit diagram illustrating a detector 1300 according to a fifth variation of the example embodiment. The operation of the detector 1300 is generally similar to the operation of the detectors 100 and 900. Specifically, the detector 1300 receives an input signal IN. The input signal IN is, for example, a wobble signal read out from an optical disk. The detector 1300 detects an envelope of the target signal IN, and outputs the detected envelope as an output signal OUT.

In the fifth variation, an integration controller 1312 is used in place of the integration controller 912 used in the detector 900. The integration controller 1312 includes, for example, a circuit similar to the attack gain controller 112 of FIG. 1, and outputs output signals of the circuit as the control signal GAJ, CN1, CN2, or CN3 indicating detection result of an unnecessary frequency component. The integration controller 1312 may control output timing of the control signal GAJ, CN1, CN2, or CN3 to be output at appropriate timing. When the input signal IN has a frequency component other than the frequency component of the target signal, the integration controller 1312 controls the envelope generator 930 to mitigate an increase in the absolute value of the output signal OUT which is an integration result. In other respects, the detector 1300 is almost similar to the detector 900 of FIG. 9.

When the control signal GAJ, CN1, CN2, or CN3 indicates that the unnecessary frequency component has been detected, the envelope generator 930 operates to mitigate an increase in the absolute value of the integral value obtained by the integrator 937. Specifically, the integration controller 1312 may output the control signal GAJ providing instructions for reducing the absolute value of the attack gain AGP as described above, or may output to the integrator 937, the control signal CN1 providing instructions for holding an integral value. The attack gain generator 934 reduces the absolute value of the attack gain AGP in accordance with the control signal GAJ. The integrator 937 holds the output integral value in accordance with the control signal CN1. The integration controller 1312 allows the integrator 937 to hold the integral value until the unnecessary frequency component is no more detected.

When the unnecessary frequency component has been detected, the integration controller 1312 may output to the data holder 938, the control signal CN2 providing instructions for holding the value in place of the control signal CN1. In this case, the data holder 938 holds the integral value output from the integrator 937 in accordance with the control signal CN2 and outputs the integral value to the selector 939. The selector 939 outputs the value hold at the data holder 938 to the integrator 937. The integration controller 1312 outputs to the integrator 937, the control signal CN1 providing instructions for setting the value input from the selector 939 to a new integral value. The integrator 937 sets the value input from the selector 939 to the new integral value.

The set value SV may be input to the selector 939, and then may be set at the integrator 937. Specifically, when the unnecessary frequency component has been detected, the integration controller 1312 may output to the selector 939, the control signal CN3 providing instructions for selecting the set value SV in place of the control signal CN1. The selector 939 selects the set value SV and outputs the set value SV to the integrator 937. The integration controller 1312 outputs to the integrator 937, the control signal CN1 providing instructions for setting the value input from the selector 939 to a new integral value. The integrator 937 sets the value input from the selector 939 to the new integral value. The set value SV is, for example, a value expected to stabilize the operation of the detector 900. Note that a preferable set value SV may be input from the outside the computing element 940.

When the unnecessary frequency component is no more detected, the integration controller 1312 outputs to the integrator 937, the control signal CN1 providing instructions for performing integration. The integrator 937 performs the integration of an output of the selector 936 in accordance with the control signal CN1.

An example has been described where the integrator 937 integrates the selected one of the attack gain AGP or the droop gain DGP. However, for example, the selector 936 may weight the attack gain AGP and the droop gain DGP in accordance with the value of the comparison result CSP, and the integrator 937 may integrate the weighted attack gain and the weighted droop gain.

Weighting is performed similarly to the weighting of the detector 100 of FIG. 1, which has been generalized for explanation. Specifically, when the comparison result CSP has an H level (i.e., a first case), the selector 936 sets the weight of the attack gain AGP to be equal to or greater than the weight where the comparison result CSP has an L level (a second case) and sets the weight of the droop gain DGP to be equal to or less than the second case. In the second case, the selector 936 sets the weight of the droop gain DGP to be equal to or greater than the weight in the first case, and sets the weight of the attack gain AGP to be equal to or less than the weight in the first case. This is also applicable to the detector 900 of FIG. 9.

Each of the embodiments of the present disclosure determines whether an input signal to the detector contains an unnecessary component such as noise, and changes the current value of the charging current or the attack gain based on the result. This enables accurate stable peak detection without tracking a noise component even if the input signal contains noise.

In each of the detectors 900, 1200, and 1300, the functional block group performing detection is implemented by the digital circuits. In other words, analog elements such as a capacitor and a current source are not used. Thus, detection characteristics of these digital circuits are not influenced by a difference in constants of analog elements. Furthermore, detectors formed by digital circuits are suitable for high integration of the circuits.

While the example embodiments of the present disclosure have been described where the detectors are peak detectors, bottom detectors may be implemented based on the above-described configurations.

In the various example embodiments, the input signals IN have been described as wobble signals read out from optical disks, the present disclosure is not limited thereto and other preferable signals may be used as long as the signals are suitable for peak detection.

The functional blocks in the specification can be typically realized as hardware. For example, the functional blocks can be formed on a semiconductor substrate as a part of an integrated circuit (IC). The IC includes a large-scale integrated circuit (LSI), an application-specific integrated circuit (ASIC), a gate array, a field programmable gate array (FPGA), etc. As an alternative, a part of or all of the functional blocks are realized as software. For example, such functional blocks are realized by a program executed in a processor. In other words, the functional blocks described in the specification may be realized as hardware, software, or a preferable combination of hardware and software.

A part of or all of the functional block groups in the above-described embodiments may be integrated by bonding. For example, the detector 100 may be realized as a hybrid integrated circuit (IC). As an alternative, a part of the detector may be realized as a hybrid IC.

As understood by those skilled in the art, various functions for realizing the present disclosure may not be integrated only in accordance with the names used in the drawings (e.g., “attack gain controller 112”). For example, a part of or all of the attack gain controller 112 may be built in a semiconductor chip including other functional blocks.

The detectors according to the example embodiments of the present disclosure are less influenced by noise. This provides the advantage of detecting a peak level or a bottom level of an input signal with high accuracy. When a detector is formed by a digital circuit, a difference in constants of analog elements does not influence detection characteristics and provides the advantage of reducing the circuit size. Therefore, the present disclosure is useful as a technique of detecting a peak level or a bottom level with high accuracy in a field performing signal processing using a peak level or a bottom level, for example, in an information recording and reproducing device, and a transmitting and receiving device in a communications apparatus.

The present disclosure is not limited to the embodiments but may be variously implemented without departing from the spirit and essential features of the present disclosure. It should be recognized that the embodiments are illustrative only and should not be taken as limiting the scope of our invention. It is intended that the scope of the invention be limited by the claims and not by the detailed description. All changes and modifications that come within the scope and range of equivalents of the claims are desired to be protected.

What is claimed is:

1. A detector configured to obtain an output signal from an input signal containing a target signal and output the output signal, the detector comprising:
an amplifier configured to receive the input signal and the output signal, compare the input signal to the output signal to output a comparison result;
an envelope generator configured to weight a first value and a second value having a sign opposite to that of the first value in accordance with the comparison result, integrate the weighted first value and the weighted second value, and output an integration result as the output signal; and
a controller configured to control the envelope generator in accordance with the input signal, wherein
the controller controls the envelope generator to mitigate an increase in an absolute value of the integration result when the input signal contains a frequency component other than a frequency component of the target signal.

2. The detector of claim 1, wherein
the envelope generator includes an attack gain generator configured to generate the first value, and
the controller controls the attack gain generator to reduce an absolute value of the first value to mitigate an increase in the absolute value of the integration result.

3. The detector of claim 2, wherein
the controller generates a signal obtained by subtracting the frequency component of the target signal from the input signal, obtains a period in which the signal obtained by subtracting is greater than a predetermined value, and as the period increases, the first value decreases.

4. The detector of claim 3, wherein
the controller reduces the first value by controlling a plurality of current sources based on the period.

5. The detector of claim 3, wherein
the controller generates three or more different values as the first value based on the period.

6. The detector of claim 1, wherein
the envelope generator includes
an attack gain generator configured to generate the first value, and
a computing element configured to integrate the first value, and
the controller allows the computing element to hold the integration result to mitigate an increase in the absolute value of the integration result.

7. A detector configured to obtain an output signal from an input signal containing a target signal and output the output signal, the detector comprising:
an amplifier configured to receive the input signal and the output signal, compare the input signal to the output signal to output a comparison result;
an envelope generator configured to weight a first value and a second value having a sign opposite to that of the first value in accordance with the comparison result, integrate the weighted first value and the weighted second value, and output an integration result as the output signal; and
a controller configured to control the envelope generator in accordance with the input signal, wherein
the controller controls the envelope generator to mitigate an increase in an absolute value of the integration result when a length of a period, in which the comparison result indicates that an absolute value of the input signal is greater than an absolute value of the output signal, is greater than a predetermined value.

8. The detector of claim 7, wherein
the controller controls the envelope generator to
generate a first gain as the first value when the length of the period is smaller than a first threshold value,
generate as the first value, a second gain having an absolute value smaller than that of the first gain when the length of the period is greater than the first threshold value, and
generate as the first value, a third gain having an absolute value smaller than that of the second gain when the length of the period is greater than a second threshold value which is greater than the first threshold value.

9. A detection method obtaining an output signal from an input signal containing a target signal, the method comprising:
comparing the input signal to the output signal;
weighting a first value and a second value having a sign opposite to that of the first value in accordance with an obtained comparison result, integrating the weighted first value and the weighted second value, and outputting an integration result as the output signal; and
mitigating an increase in an absolute value of the integration result when the input signal contains a frequency component other than a frequency component of the target signal.

10. The detection method of claim 9, wherein
an absolute value of the first value is reduced to mitigate an increase in the absolute value of the integration result.

11. The detection method of claim 9, wherein
the integration result is held to mitigate an increase in the absolute value of the integration result.

12. A detection method obtaining an output signal from an input signal containing a target signal, the method comprising:
comparing the input signal to the output signal;
weighting a first value and a second value having a sign opposite to that of the first value in accordance with an obtained comparison result, integrating the weighted first value and the weighted second value, and outputting an integration result as the output signal; and
mitigating an increase in an absolute value of the integration result when a length of a period, in which the comparison result indicates that an absolute value of the input signal is greater than an absolute value of the output signal, is greater than a predetermined value.
